(19) United States
(12) Patent Application Publication
(10) Pub. No.: US 2020/0099005 A1
(43) Pub. Date: Mar. 26, 2020

(54) ORGANIC ELECTROLUMINESCENT ELEMENT AND LIGHTING DEVICE

(71) Applicant: LUMIOTEC INC., Yonezawa-shi, Yamagata (JP)

(72) Inventor: Junichi TANAKA, Yonezawa-shi (JP)

(73) Assignee: LUMIOTEC INC., Yonezawa-shi, Yamagata (JP)

(21) Appl. No.: 16/468,805

(22) PCT Filed: Dec. 27, 2017
(86) PCT No.: PCT/JP2017/047117

§ 371 Date: Jun. 12, 2019

(30) Foreign Application Priority Data
Dec. 27, 2016 (JP) 2016-254304

(51) Int. Cl. H01L 51/50; H05B 33/04; H05B 33/26

(52) U.S. Cl. CPC H01L 51/5012; H05B 33/04; H01L 2251/5338; H01L 51/5064; H01L 51/508; H05B 33/26

(57) ABSTRACT

The organic electroluminescent element comprises, between a first electrode and a second electrode, a light-emitting unit including at least a light-emitting layer made from an organic compound. The organic electroluminescent element comprises at least one light-emitting unit including a light-emitting layer formed of a red light-emitting layer which emits red light having a peak wavelength in the red wavelength range. The red light obtained by light emission from the light-emitting unit has a peak wavelength in the red wavelength range of 590-640 nm. The difference between the peak wavelength of the red light and the dominant wavelength of the red light is 10 nm or less.

### TECHNICAL FIELD

The present invention relates to an organic electroluminescent element and a lighting device including the same.

The present application claims the benefit of priority of Japanese Patent Application No. 2016-254304 filed on Dec. 27, 2016, the contents of which are incorporated herein by reference.

### BACKGROUND ART

An organic electroluminescent element (hereafter, also referred to as “organic EL element” for short) is a self-luminescent element including a light emitting layer, made of an organic compound, between a cathode and an anode facing each other. When voltage is applied between the cathode and the anode, electrons injected into the light emitting layer from the cathode side and holes injected into the light emitting layer from the anode side recombine in the light emitting layer to form excitons and the excitons causes the organic EL element to emit light.

As an organic EL element capable of achieving high luminance and long lifetime, there is known an element with a multi-photon emission structure (hereafter, referred to as “MPE element” for short) in which a light emitting unit including at least one light emitting layer is considered as one unit and an electrically-insulating charge generating layer is arranged between multiple light emitting units (for example, see Patent Document 1). In the MPE element, when voltage is applied between a cathode and an anode, charges in a charge transfer complex move to the cathode side and the anode side. In the MPE element, holes are thereby injected into one light emitting unit located on the cathode side of the charge generating layer and electrons are injected into another light emitting unit located on the anode side of the charge generating layer. In such an MPE element, since light can be simultaneously emitted from the multiple light emitting units with the same current amount, a current efficiency and an external quantum efficiency multiplied by the number of the light emitting units can be achieved.

The MPE element can provide white light of various color temperatures by combining light emitting units which emit light of different colors. High efficiency is easier to achieve in an MPE element which emits white light of a warm color than in MPE elements which emit white light of other colors. In the white light of warm color, optimization of red light which is the main component of the white light leads to an increase in the efficiency of white light. The special color rendering index R9 indicating reproducibility of red is known to be used as an index for achieving such optimization of the red light (see, for example, Patent Document 2).

However, for color light other than the white light such as red and yellow light, the special color rendering index R9 cannot be used as the index for achieving optimization of the color light which leads to an increase in the efficiency.

### PRIOR ART DOCUMENT

### Patent Document

Patent Document 1: Japanese Patent Application Publication No. 2003-272860

Patent Document 2: Japanese Patent Application Publication No. 2016-66542

### SUMMARY OF THE INVENTION

### Problems to be Solved by the Invention

The present invention has been proposed in view of the aforementioned conventional circumstances and an object thereof is to provide an organic electroluminescent element which emits color light other than white light with high luminous efficiency and which is suitable fora special lighting device such as an automobile lighting device and to provide a lighting device including this organic electroluminescent element.

### Means for Solving the Problems

To achieve the above object, the following aspects are provided.

(1) An organic electroluminescent element having a light emitting unit including a light emitting layer made of at least an organic compound between a first electrode and a second electrode, characterized in that

the organic electroluminescent element comprises at least one light emitting unit including a light emitting layer formed of a red light emitting layer which emits red light with a peak wavelength in a red wavelength band,

the red light produced by light emission of the light emitting unit has the peak wavelength in a red wavelength band of 590 nm to 640 nm, and

a difference between the peak wavelength of the red light and a dominant wavelength of the red light is 10 nm or less.

(2) The organic electroluminescent element according to the above aspect (1), characterized in that

the red light emitting layer has one or two peak wavelengths in the red wavelength band, and

the red light produced by the light emission of the light emitting unit has one or two peak wavelengths in the red wavelength band of 590 nm to 640 nm.

(3) The organic electroluminescent element according to the above aspect (1) or (2), characterized in that the red light emitting layer is formed of a red fluorescent light emitting layer containing a red fluorescent material.
(4) The organic electroluminescent element according to the above aspect (3), characterized in that the red light provided by the light emitting unit including the red fluorescent light emitting layer includes a delayed fluorescence component.
(5) The organic electroluminescent element according to the above aspect (1) or (2), characterized in that the red light emitting layer is formed of a red phosphorescent light emitting layer containing a red phosphorescent material.
(6) The organic electroluminescent element according to anyone of the above aspects (1) to (5), characterized in that

the organic electroluminescent element comprises two of the light emitting units which are identical, and

the light emitting units emit red light with the same peak wavelength.

(7) The organic electroluminescent element according to anyone of the above aspects (1) to (5), characterized in that

the organic electroluminescent element comprises two of the light emitting units which are different from each other, and

the light emitting units emit red light with different peak wavelengths, respectively.

(8) The organic electroluminescent element according the above aspect (7), characterized in that the red light has one peak wavelength in a red wavelength band of 590 nm to 620 nm and one peak wavelength in a red wavelength band of 625 nm to 640 nm.
(9) The organic electroluminescent element according to anyone of the above aspects (1) to (8) , the organic electroluminescent element having a structure in which a plurality of light emitting units each including a light emitting layer made of at least an organic compound are stacked one on top of the other between the first electrode and the second electrode with a charge generating layer sandwiched between the light emitting units, the organic electroluminescent element capable of providing the red light by causing the plurality of light emitting units to emit light, characterized in that

the organic electroluminescent element comprises:
a first red light emitting unit formed of the light emitting unit; and
a second red light emitting unit formed of the light emitting unit,

the first red light emitting unit and the second red light emitting unit are stacked one on top of the other with a first charge generating layer sandwiched therebetween, and

the organic electroluminescent element has a structure in which the second electrode, the second red light emitting unit, the first charge generating layer, the first red light emitting unit, and the first electrode are stacked one on top of another in this order.

(10) The organic electroluminescent element according to any one of the above aspects (1) to (8), the organic electroluminescent element having a structure in which a plurality of light emitting units each including a light emitting layer made of at least an organic compound are stacked one on top of another between the first electrode and the second electrode with a charge generating layer sandwiched between each pair of the adjacent light emitting units, the organic electroluminescent element capable of providing the red light by causing the plurality of light emitting units to emit light, characterized in that

the organic electroluminescent element comprises:
a first red light emitting unit formed of the light emitting unit;
a second red light emitting unit formed of the light emitting unit; and
a third red light emitting unit formed of the light emitting unit,

the first light emitting unit and the second red light emitting unit are stacked one on top of the other with a first charge generating layer sandwiched therebetween,

the second light emitting unit and the third red light emitting unit are stacked one on top of the other with a second charge generating layer sandwiched therebetween, and

the organic electroluminescent element has a structure in which the second electrode, the third light emitting unit, the second charge generating layer, the second red light emitting unit, the first charge generating layer, the first red light emitting unit, and the first electrode are stacked one on top of another in this order.

(11) The organic electroluminescent element according to the above aspect (9) or (10), characterized in that

the charge generating layer is formed of an electrically insulating layer made of an electron accepting material and an electron donating material, and

a specific resistance of the electrically insulating layer is 1.0×10² Ω·cm or more.

(12) The organic electroluminescent element according to the above aspect (11), characterized in that the specific resistance of the electrically insulating layer is 1.0×10⁵ Ω·cm or more.
(13) The organic electroluminescent element according to the above aspect (9) or (10), characterized in that

the charge generating layer is formed of a mixed layer of different materials and one component of the mixed layer forms a charge transfer complex by redox, and

when voltage is applied between the first electrode and the second electrode, charges in the charge transfer complex move to the first electrode side and the second electrode side to cause holes to be injected into one light emitting unit located on the first electrode side of the charge generating layer and cause electrons to be injected into another light emitting unit located on the second electrode side of the charge generating layer.

(14) The organic electroluminescent element according to the above aspect (9) or (10), characterized in that

the charge generating layer is formed of a laminate of an electron accepting material and an electron donating material, and

when voltage is applied between the first electrode and the second electrode, in an interface between the electron accepting material and the electron donating material, charges generated by reaction involving electron transfer between the electron accepting material and the electron donating material move to the first electrode side and the second electrode side to cause holes to be injected into one light emitting unit located on the first electrode side of the charge generating layer and cause electrons to be injected into another light emitting unit located on the second electrode side of the charge generating layer.

(15) The organic electroluminescent element according to any one of the above aspects (9) to (14) , characterized in that the charge generating layers contain a compound having a structure expressed by formula (1):

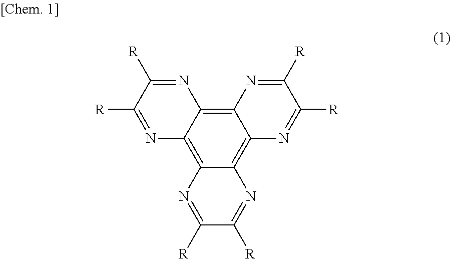

where R represents an electron withdrawing group of F, Cl, Br, I, CN, or CF₃.
(16) Alighting device characterized in that the lighting device comprises the organic electroluminescent element according to any one of the above aspects (1) to (15).
(17) The lighting device according to the above aspect (16), characterized in that the lighting device comprises an optical film on a light extraction surface side of the organic electroluminescent element.
(18) The lighting device according to the above aspect (17), characterized in that

the lighting device comprises a base substrate and a sealing substrate which are formed of flexible substrates, and

the lighting device is flexible.

### Effect of the Invention

According to the one aspect described above, it is possible to provide an organic electroluminescent element which emits color light other than white light with high luminous efficiency and which is suitable for a special lighting device such as an automobile lighting device and to provide a lighting device including this organic electroluminescent element.

### BRIEF DESCRIPTION OF THE DRAWINGS

FIG. 1 is a cross-sectional view illustrating a schematic configuration of an organic EL element according to a first embodiment of the present invention.

FIG. 2 is a cross-sectional view illustrating a schematic configuration of an organic EL element according to a second embodiment of the present invention.

FIG. 3 is a cross-sectional view illustrating a schematic configuration of an organic EL element according to a third embodiment of the present invention.

FIG. 4 is a cross-sectional view illustrating a schematic configuration of an embodiment of a lighting device of the present invention.

FIG. 5 is a graph depicting relationships between an external quantum efficiency and a difference between a peak wavelength (A) of red light and a dominant wavelength (B) of the red light in each of organic EL elements of Experimental Examples 1 to 6.

FIG. 6 is a graph depicting relationships between the external quantum efficiency and the dominant wavelength (B) of the red light in each of the organic EL elements of Experimental Examples 1 to 6.

### MODE FOR CARRYING OUT THE INVENTION

Detailed description is given of embodiments of an organic electroluminescent element of the present invention and a lighting device including the same with reference to the drawings.

Note that, for the sake of convenience, in the drawings used in the following description, characteristic parts are sometimes illustrated in an enlarged manner to facilitate understanding of characteristics, and proportions of dimensions of constitutional elements and the like are not always the same as actual ones. Moreover, materials, dimensions, and the like exemplified in the following description are merely examples and the present invention are not necessarily limited to those and can be carried out with the materials, dimensions, and the like appropriately changed within a scope not changing the spirit of the invention.

### First Embodiment

### Organic Electroluminescent Element (Organic EL Element)

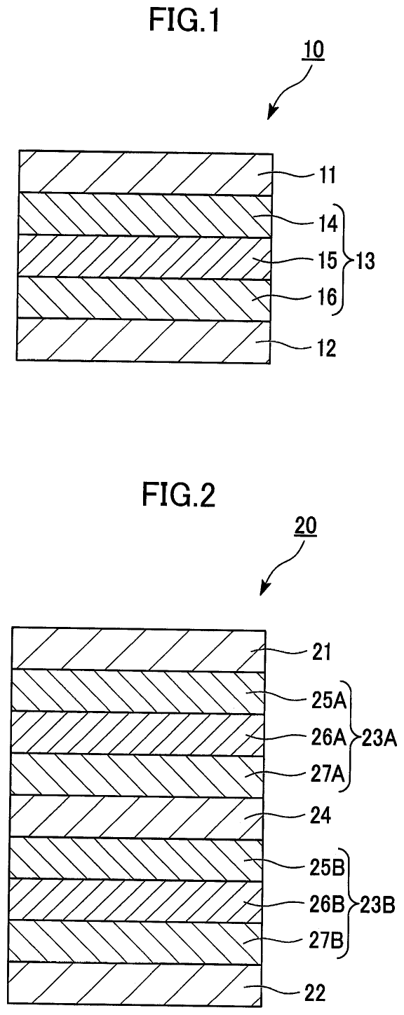

FIG. 1 is a cross-sectional view illustrating a schematic configuration of an organic EL element according to a first embodiment of the present invention.

As illustrated in FIG. 1, the organic EL element 10 of the embodiment has one light emitting unit 13 including a light emitting layer made of at least an organic compound, between a first electrode 11 and a second electrode 12. The organic EL element 10 is an organic EL element capable of providing red light by causing the light emitting unit 13 to emit light.

The light emitting unit 13 includes a light emitting layer 15 formed of a red fluorescent light emitting layer or a red phosphorescent light emitting layer which emits red light with one or two peak wavelengths in a red wavelength band. The red light provided by the light emitting unit 13 including the red fluorescent light emitting layer may include a delayed fluorescence component.

The organic EL element 10 of the embodiment has a structure in which the second electrode 12, the light emitting unit 13, and the first electrode 11 are stacked one on top of another in this order.

In the organic EL element 10 of the embodiment, the red light produced by the light emission of the light emitting unit 13 has one or two peak wavelengths in a red wavelength band of 590 nm to 640 nm.

In the organic EL element 10 of the embodiment, a difference between a peak wavelength of the red light and a dominant wavelength of the red light is 10 nm or less.

When the difference between the peak wavelength of the red light and the dominant wavelength of the red light is 10 nm or less, the organic EL element 10 can efficiently provide the color light (red light) of the light emitting unit 13. Accordingly, the organic EL element 10 can provide color light suitable as illumination light with high luminous efficiency. Moreover, the external quantum efficiency (EQE) of the organic EL element 10 is improved.

When the difference between the peak wavelength of the red light and the dominant wavelength of the red light is greater than 10 nm, a peak wavelength not included in an original light emission component (red light component) is emphasized by an interference effect and the luminous efficiency decreases.

The dominant wavelength is a quantified value of the color (single wavelength) perceived by the human eye. The sensitivity of the human eye to light is dependent on the wavelength, and the peak wavelength at which the light emission intensity is highest is different from the wavelength actually perceived by the human eye.

A chromaticity diagram is a diagram in which values (chromaticity) of x and y are expressed on an orthogonal coordinate system. When x and y of various types of monochromatic light in the spectrum are calculated over the entire visible wavelength band and the coordinates of x and y are plotted, a horseshoe-shaped curve with a straight line extending from violet to red of the chromaticity diagram is obtained. This curve is referred to as spectrum locus. Moreover, a corner of violet in this curve corresponds to wavelength of 380 nm and a corner of red corresponds to 780 nm.

The dominant wavelength is measured as follows. In the chromaticity diagram, a straight line is drawn from a chromatic point of white (x=y=0.33) to a point (chromatic point) where the chromaticity of the light (red light in this case) emitted by the organic EL element 10 is plotted. A monochromatic light wavelength of a point where the drawn straight line and the spectrum locus intersect is determined as the dominant wavelength.

The external quantum efficiency is a ratio obtained by dividing the number of photons extracted to the outside by the number of carriers injected into the inside of the element and can be used as an index of luminous efficiency.

Generally, a metal with a small work function, an alloy of such a metal, a metal oxide, or the like is preferably used as the first electrode 11. For example, as a metal forming the first electrode 11, it is possible to use a metal single substance like an alkaline metal such as lithium (Li), an alkaline earth metal such as magnesium (Mg) or calcium (Ca), or a rare-earth metal such as europium (Eu) or use an alloy containing any of these metals and aluminum (Al) , silver (Ag), indium (In), or the like.

Alternatively, the first electrode 11 may have a configuration in which an organic layer doped with a metal is used in an interface between the first electrode 11 and an organic layer as described in, for example, “Japanese Patent Application Publication No. Hei 10-270171” and “Japanese Patent Application Publication No. 2001-102175.” In this case, it is only necessary to use an electrically conductive material as the material of the first electrode 11 and the material is not limited to one with particular properties such as the work function.

As another alternative, the first electrode 11 may have a configuration in which an organic layer in contact with the first electrode 11 is made of an organic metal complex compound containing at least one type selected from the group consisting of alkali metal ions, alkaline earth metal ions, and rare-earth metal ions as described in, for example, “Japanese Patent Application Publication No. Hei 11-233262” and “Japanese Patent Application Publication No. 2000-182774.” In this case, a metal capable of reducing the metal ions contained in the organic metal complex compound to metal in vacuum, for example, a metal (with a thermal reduction property) such as aluminum (Al), zirconium (Zr) , titanium (Ti) , and silicon (Si) or an alloy containing any of these metals can be used as the first electrode 11. Among these, Al which is generally widely used as a wiring electrode is particularly preferable from the viewpoint of ease of vapor deposition, high light reflectance, chemical stability, and the like.

The material of the second electrode 12 is not limited to a particular material. When light is to be extracted from the second electrode 12 side, a transparent, electrically conductive material such as, for example, ITO (Indium Tin Oxide) or IZO (Indium Zinc Oxide) can be used.

Moreover, in contrary to a general organic EL element, light can be extracted from the first electrode 11 side by using a metal material or the like for the second electrode 12 and using a transparent, electrically conductive material for the first electrode 11. For example, by employing the method described in “Japanese Patent Application Publication No. 2002-332567,” the first electrode 11 made of the aforementioned transparent, electrically conductive material such as ITO and IZO can be formed by sputtering which does not damage an organic film.

Accordingly, when both of the first electrode 11 and the second electrode 12 are formed to be transparent, since the light emitting unit 13 is also similarly transparent, it is possible to manufacture a transparent organic EL element 10.

Note that the order of film formation does not have to start from the second electrode 12 side and may start from the first electrode 11 side.

The light emitting unit 13 is formed of an electron transport layer 14, a light emitting layer 15, and a hole transport layer 16.

The light emitting unit 13 may employ any of various structures similar to those of conventionally-known organic EL elements and may have any laminated structure as long as it includes light emitting layers made of at least an organic compound. For example, the light emitting unit 13 may be configured such that an electron injection layer, a hole blocking layer, and the like are arranged on the first electrode 11 side of the light emitting layer 15 and a hole injection layer, an electron blocking layer, and the like are arranged on the second electrode 12 side of the light emitting layer 15.

The electron transport layer 14 is made of, for example, a conventionally well-known electron transport material. In the organic EL element 10 of the embodiment, an electron transport material with a relatively deep HOMO (Highest Occupied Molecular Orbital) level is preferably used among electron transport materials generally used for organic EL elements. Specifically, an electron transport material with a HOMO level of at least about 6.0 eV is preferably used. For example, 4,7-Diphenyl-1,10-phenanthroline (Bphen), 2,2′, 2″-(1,3,5-Benzinetriyl)-tris(1-phenyl-1-H-benzimidazole) (TPBi), and the like can be used as such an electron transport material.

Moreover, the electron transport layer 14 may be formed of one layer or two or more layers.

The electron injection layer is provided between the first electrode 11 and the electron transport layer 14 to improve injection efficiency of electrons from the first electrode 11. An electron transport material having properties similar to the electron transport layer 14 can be used as the material of the electron injection layers. The electron transport layer 14 and the electron injection layer are sometimes collectively referred to as electron transport layer.

The hole transport layer 16 is made of, for example, a conventionally well-known hole transport material. The hole transport material is not limited to a particular material. For example, an organic compound (electron donating material) which has an ionization potential less than 5.7 eV and which has a hole transport property, that is an electron donating property is preferably used as the hole transport material. For example, an arylamine compound such as 4,4′-bis-[N-(2-naphthyl)-N-phenyl-amino]biphenyl (α-NPD) or the like can be used as the electron donating material.

The hole injection layer is provided between the second electrode 12 and the hole transport layer 16 to improve injection efficiency of holes from the second electrode 12. An electron donating material having properties similar to the hole transport layers can be used as the material of the hole injection layer. The hole transport layer and the hole injection layer are sometimes collectively referred to as the hole transport layer.

The light emitting layer 15 included in the light emitting unit 13 is formed of the red fluorescent light emitting layer containing a red fluorescent material or the red phosphorescent light emitting layer containing a red phosphorescent material.

The red fluorescent light emitting layer and the red phosphorescent light emitting layer each contain a host material which is a main component and a guest material which is a minor component as the organic compound. Emission of the red light is attributable particularly to the properties of the guest material.

As the host material of the light emitting layer 15 included in the light emitting unit 13, a material with an electron transport property, a material with a hole transport property, a material obtained by mixing these materials, or the like can be used. Specifically, as the host material of the red phosphorescent light emitting layer, 4,4′-biscarbazolylbiphenyl (CBP), 2,9-dimethyl-4,7-diphenyl-9,10-phenanthroline (BCP), or the like can be used. As the host material of the red fluorescent light emitting layer, for example, 4,4′-bis (2,2-diphenylvinyl)-1,1′-biphenyl (DPVBi), tris (8-hydroxyquinolinato) aluminum (Alq₃) , or the like can be used.

The guest material of the light emitting layer 15 included in the light emitting unit 13 is also referred to as dopant material. The guest material utilizing fluorescent light emission is generally referred to as fluorescent light emitting material. A light emitting layer made of the fluorescent light emitting material is referred to as fluorescent light emitting layer. Meanwhile, the guest material utilizing phosphorescent light emission is generally referred to as phosphorescent light emitting material. A light emitting layer made of the phosphorescent light emitting material is referred to as phosphorescent light emitting layer.

In the phosphorescent light emitting layer out of these layers, it is possible to utilize not only 75% of triplet excitons, which are generated by recombination of electrons and holes, but also 25% of the triplet excitons, which are generated by energy transfer from singlet excitons. Accordingly, an internal quantum efficiency of 100% can be achieved in theory. Specifically, the excitons generated by the recombination of electrons and holes are converted to light in the light emitting layer without thermal quenching or the like. In an organic metal complex including heavy atoms such as iridium or platinum, an internal quantum efficiency close to 100% is actually achieved by optimization of the element structure and the like.

As the guest material of the red phosphorescent light emitting layer, a red phosphorescent light emitting material such as Ir(piq)₃ or Ir(btpy)₃ can be used.

As the guest material of the red fluorescent light emitting layer, a material such as DCJTB can be used.

For example, a vacuum deposition method, a spin coating method, or the like can be used as a film forming method of the layers forming the light emitting unit 13.

As described above, in the organic EL element 10 of the embodiment, since the difference between the peak wavelength of the red light and the dominant wavelength of the red light is 10 nm or less, the organic EL element 10 can provide the red light with high luminous efficiency.

The organic EL element 10 of the embodiment can be thereby preferably used in a special lighting device such as an automobile lighting device.

### Second Embodiment

### Organic EL Element

FIG. 2 is a cross-sectional view illustrating a schematic configuration of an organic EL element according to a second embodiment of the present invention.

As illustrated in FIG. 2, the organic EL element 20 of the embodiment has a structure in which multiple light emitting units 23A, 23B each including a light emitting layer made of at least an organic compound are stacked one on top of the other between a first electrode 21 and a second electrode 22 with a charge generating layer (CGL) 24 sandwiched between the light emitting units 23A, 23B. The organic EL element 20 is an organic EL element capable of providing red light by causing the multiple light emitting units 23A, 23B to emit light.

The organic EL element 20 of the embodiment includes the first light emitting unit 23A and the second light emitting unit 23B.

The first light emitting unit 23A and the second light emitting unit 23B are red light emitting units.

The first light emitting unit 23A and the second light emitting unit 23B include light emitting layers 26A, 26B each formed of a red fluorescent light emitting layer or a red phosphorescent light emitting layer which emits red light with one or two peak wavelengths in a red wavelength band. The red light provided by the first light emitting unit 23A and the second light emitting unit 23B including the red fluorescent light emitting layers may include a delayed fluorescence component.

The first light emitting unit 23A and the second light emitting unit 23B are stacked one on top of the other with the charge generating layer 24 sandwiched therebetween.

The organic EL element 20 of the embodiment has a structure in which the second electrode 22, the second light emitting unit 23B, the charge generating layer 24, the first light emitting unit 23A, and the first electrode 21 are stacked one on top of another in this order. Specifically, the organic EL element 20 of the embodiment has an MPE structure in which the first light emitting unit 23A and the second light emitting unit 23B are stacked one on top of the other with the charge generating layer 24 sandwiched therebetween.

In the organic EL element 20 of the embodiment, the red light produced by the light emission of the first light emitting unit 23A and the second light emitting unit 23B has one or two peak wavelengths in the red wavelength band of 590 nm to 640 nm.

The first light emitting unit 23A and the second light emitting unit 23B may have the same configuration and emit red light with the same peak wavelength.

Alternatively, the first light emitting unit 23A and the second light emitting unit 23B may have different configurations and emit red light with different peak wavelengths, respectively. In this case, the first light emitting unit 23A and the second light emitting unit 23B have one peak wavelength in a red wavelength band of 590 nm to 620 nm and one peak wavelength in a red wavelength band of 625 nm to 640 nm.

In the organic EL element 20 of the embodiment, a difference between a peak wavelength of the red light and a dominant wavelength of the red light is 10 nm or less.

When the difference between the peak wavelength of the red light and the dominant wavelength of the red light is 10 nm or less, the organic EL element 20 can efficiently provide the color light (red light) of the first light emitting unit 23A and the color light (red light) of the second light emitting unit 23B. Accordingly, the organic EL element 20 can provide color light suitable as illumination light with high luminous efficiency.

When the difference between the peak wavelength of the red light and the dominant wavelength of the red light is greater than 10 nm, a peak wavelength not included in an original light emission component (red light component) is emphasized by an interference effect and the luminous efficiency decreases.

The same electrode as the first electrode 11 in the aforementioned first embodiment can be used as the first electrode 21.

The same electrode as the second electrode 12 in the aforementioned first embodiment can be used as the second electrode 22.

The first light emitting unit 23A is formed of a first electron transport layer 25A, a first light emitting layer 26A, and a first hole transport layer 27A. The second light emitting unit 23B is formed of a second electron transport layer 25B, a second light emitting layer 26B, and a second hole transport layer 27B.

The first light emitting unit 23A and the second light emitting unit 23B may employ any of various structures similar to those of conventionally-known organic EL elements and may have any laminated structure as long as they include red light emitting layers made of at least an organic compound. For example, each of the first light emitting unit 23A and the second light emitting unit 23B maybe configured such that an electron injection layer, a hole blocking layer, and the like are arranged on the first electrode 21 side of the red light emitting layer and a hole injection layer, an electron blocking layer, and the like are arranged on the second electrode 22 side of the light emitting layer.

The first electron transport layer 25A and the second electron transport layer 25B have the same configuration as that of the electron transport layer 14 in the aforementioned first embodiment.

The first hole transport layer 27A and the second hole transport layer 27B have the same configuration as that of the hole transport layer 16 in the aforementioned first embodiment.

The first light emitting layer 26A included in the first light emitting unit 23A and the second light emitting layer 26B included in the second light emitting unit 23B have the same configuration as that of the light emitting layer 15 in the aforementioned first embodiment.

The charge generating layer 24 is formed of an electrically insulating layer made of an electron accepting material and an electron donating material. The specific resistance of the electrically insulating layer is preferably 1.0×10² Ω·cm or more, more preferably 1.0×10⁵ Ω·cm or more.

Alternatively, the charge generating layer 24 may be a mixed layer of different materials in which one component of the mixed layer forms a charge transfer complex by redox. In this case, when voltage is applied between the first electrode 21 and the second electrode 22, charges in the charge transfer complex move to the first electrode 21 side and the second electrode 22 side. In the organic EL element 20, holes are thereby injected into the first light emitting unit 23A located on the first electrode 21 side of the charge generating layer 24. Moreover, in the organic EL element 20, electrons are injected into the second light emitting unit 23B located on the second electrode 22 side of the charge generating layer 24. Light can be thereby simultaneously emitted from the first light emitting unit 23A and the second light emitting unit 23B with the same current amount. Accordingly, a current efficiency and an external quantum efficiency proportionate to the sum of luminous efficiencies of the first light emitting unit 23A and the second light emitting unit 23B can be obtained.

Alternatively, the charge generating layer 24 may be a laminate of an electron accepting material and an electron donating material. In this case, when voltage is applied between the first electrode 21 and the second electrode 22, in an interface between the electron accepting material and the electron donating material, charges generated by reaction involving electron transfer between these electron accepting material and electron donating material move to the first electrode 21 side and the second electrode 22 side. In the organic EL element 20, holes are thereby injected into the first light emitting unit 23A located on the first electrode 21 side of the charge generating layer 24. Moreover, in the organic EL element 20, electrons are injected into the second light emitting unit 23B located on the second electrode 12 side of the charge generating layer 24. Light can be thereby simultaneously emitted from the first light emitting unit 23A and the second light emitting unit 23B with the same current amount. Accordingly, a current efficiency and an external quantum efficiency proportionate to the sum of luminous efficiencies of the first light emitting unit 23A and the second light emitting unit 23B can be obtained.

For example, materials described in Japanese Patent Application Publication No. 2003-272860 can be used as materials forming the charge generating layer 24. Among these, materials described in paragraphs [0019] to [0021] can be preferably used. Alternatively, materials described in paragraphs [0023] to [0026] of “International Patent Application Publication No. WO2010/113493” can be used as materials forming the charge generating layer 24. Among these, a strong electron accepting material (HATCN6) described in paragraphs [0059] in particular can be preferably used. When substituent groups represented by R in the structure expressed by the following formula (1) are CN (cyano groups), this compound is HATCN6 described above.

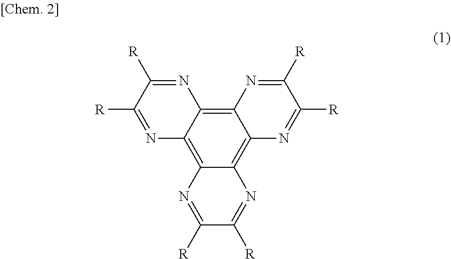

where R represents an electron withdrawing group of F, Cl, Br, I, CN, or CF₃

As described above, in the organic EL element 20 of the embodiment, the difference between the peak wavelength of the red light and the dominant wavelength of the red light is 10 nm or less. Accordingly, the organic EL element 20 can provide the red light with high luminous efficiency. Moreover, the organic EL element 20 of the embodiment has the MPE structure in which the first light emitting unit 23A and the second light emitting unit 23B are stacked one on top of the other with the charge generating layer 24 sandwiched between the light emitting units 23A, 23B. Accordingly, the organic EL element 20 can provide orange light while achieving high-luminance light emission and long-life driving.

The organic EL element 20 of the embodiment can be thereby preferably used in a special lighting device such as an automobile lighting device.

When the light emission intensity of an organic EL element in a forward direction is to be improved, generally, a distance dl from the first light emitting layer to the first electrode and a distance d3 from a second light emitting layer to the first electrode are set to satisfy (2N+1) λ/4n (N is a positive integer, λ is a peak wavelength in light emission of the organic EL element, and n is an average refractive index of layers forming the organic EL element) . Moreover, a distance d2 including the film thickness from the first light emitting layer to the second electrode and a distance d4 including the film thickness from the second light emitting layer to the second electrode are set to satisfy 2Nλ/4n (N is a positive integer, λ is a peak wavelength in light emission of the organic EL element, and n is an average refractive index of layers forming the organic EL element). It is known that this can improve the luminous efficiency by means of an interference effect between light emission of the first light emitting layer and light emission of the second light emitting layer. In this case, the first electrode corresponds to a cathode and the second electrode corresponds to an anode.

In an organic EL element in which the difference between the peak wavelength of the red light and the dominant wavelength of the red light is greater than 10 nm, for example, the distance between the first light emitting layer and the second electrode and the distance between the second light emitting layer and the second electrode deviate greatly from reference film thicknesses to be described later. In other words, in a design using the aforementioned interference effect, an organic EL element with high luminous efficiency can be achieved by reducing the deviation of the distance between the first light emitting layer and the second electrode from the reference film thickness for this distance and the deviation of the distance between the second light emitting layer and the second electrode from the reference film thickness for this distance.

However, in a general organic EL element, the optical film thickness varies depending on shifting of a light emitting region caused by differences in charge transport capabilities of the respective layers. Accordingly, the element structure cannot be optimized merely by setting the film thickness of each layer equal to the reference film thickness. Thus, organic EL elements in which the difference between the peak wavelength of the red light and the dominant wavelength of the red light is 10 nm or less are manufactured to quantify effects of the aforementioned deviation from the reference film thickness and the variation in the optical film thickness caused by the shifting of the light emitting region. The luminous efficiency of the organic EL element can be thereby improved. As a result, a guideline for design of the organic EL element can be made clearer.

The organic EL element 20 of the embodiment can be thereby preferably used in a special lighting device such as an automobile lighting device.

### Third Embodiment

### Organic EL Element

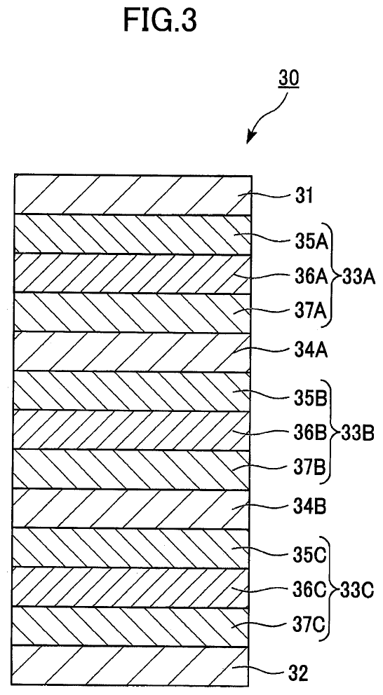

FIG. 3 is a cross-sectional view illustrating a schematic configuration of an organic EL element according to a third embodiment of the present invention.

As illustrated in FIG. 3, the organic EL element 30 of the embodiment has a structure in which multiple light emitting units 33A, 33B, 33C each including a light emitting layer made of at least an organic compound are stacked one on top of another between a first electrode 31 and a second electrode 32 with each of charge generating layers (CGL) 34A, 34B sandwiched between a corresponding pair of the adjacent light emitting units. The organic EL element 30 is an organic EL element capable of providing red light by causing the multiple light emitting units 33A, 33B, 33C to emit light.

The organic EL element 30 of the embodiment includes the first light emitting unit 33A, the second light emitting unit 33B, and the third light emitting unit 33C.

The first light emitting unit 33A, the second light emitting unit 33B, and the third light emitting unit 33C are red light emitting units.

The red light emitting units include light emitting layers 36A, 36B, 36C each formed of a red fluorescent light emitting layer or a red phosphorescent light emitting layer which emits red light with one or two peak wavelengths in a red wavelength band. The red light provided by the first light emitting unit 23A, the second light emitting unit 23B, and the third light emitting unit 33C including the red fluorescent light emitting layers may include a delayed fluorescence component.

The first light emitting unit 33A and the second light emitting unit 33B are stacked one on top of the other with the first charge generating layer 34A sandwiched therebetween. The second light emitting unit 33B and the third light emitting unit 33C are stacked one on top of the other with the second charge generating layer 34B sandwiched therebetween.

The organic EL element 30 of the embodiment has a structure in which the second electrode 32, the third light emitting unit 33C, the second charge generating layer 34B, the second light emitting unit 33B, the first charge generating layer 34A, the first light emitting unit 33A, and the first electrode 31 are stacked one on top of another in this order. Specifically, the organic EL element 30 of the embodiment has an MPE structure in which the first light emitting unit 33A, the second light emitting unit 33B, and the third light emitting unit 33C are stacked one on top of another with each of the first charge generating layer 34A and the second charge generating layer 34B, sandwiched between the corresponding pair of adjacent light emitting units.

In the organic EL element 30 of the embodiment, the red light produced by the light emission of the first light emitting unit 33A, the second light emitting unit 33B, and the third light emitting unit 33C has one or two peak wavelengths in the red wavelength band of 590 nm to 640 nm.

The first light emitting unit 33A, the second light emitting unit 33B, and the third light emitting unit 33C may have the same configuration and emit red light with the same peak wavelength.

Alternatively, the organic EL element 30 may be configured such that two of the three light emitting units have the same configuration while the other one has a configuration different from the two and the light emitting units with the same configuration emit red light with the same peak wavelength while the light emitting unit with the different configuration emit red light with a different peak wavelength. In this case, the red light emitted from the light emitting units with the same configuration has one peak wavelength in a red wavelength band of 590 nm to 620 nm and the red light emitted from the light emitting unit with the different configuration has one peak wavelength in a red wavelength band of 625 nm to 640 nm. Alternatively, the configuration may be such that the red light emitted from the light emitting units with the same configuration has one peak wavelength in the red wavelength band of 625 nm to 640 nm and the red light emitted from the light emitting unit with the different configuration has one peak wavelength in the red wavelength band of 590 nm to 620 nm.

In the organic EL element 30 of the embodiment, a difference between a peak wavelength of the red light and a dominant wavelength of the red light is 10 nm or less.

When the difference between the peak wavelength of the red light and the dominant wavelength of the red light is 10 nm or less, the organic EL element 30 can efficiently provide the color light (red light) of the first light emitting unit 33A, the color light (red light) of the second light emitting unit 33B, and the color light (red light) of the third light emitting unit 33C. Accordingly, the organic EL element 20 can provide color light suitable as illumination light with high luminous efficiency. Moreover, the external quantum efficiency (EQE) of the organic EL element 30 is improved.

When the difference between the peak wavelength of the red light and the dominant wavelength of the red light is greater than 10 nm, a peak wavelength not included in an original light emission component (red light component) is emphasized by an interference effect and the luminous efficiency decreases.

The same electrode as the first electrode 11 in the aforementioned first embodiment can be used as the first electrode 31.

The same electrode as the second electrode 12 in the aforementioned first embodiment can be used as the second electrode 32.

The first light emitting unit 33A is formed of a first electron transport layer 35A, a first light emitting layer 36A, and a first hole transport layer 37A. The second light emitting unit 33B is formed of a second electron transport layer 35B, a second light emitting layer 36B, and a second hole transport layer 37B. The third light emitting unit 33C is formed of a third electron transport layer 35C, a third light emitting layer 36C, and a third hole transport layer 37C.

The first light emitting unit 33A, the second light emitting unit 33B, and the third light emitting unit 33C may employ any of various structures similar to those of conventionally-known organic EL elements. The first light emitting unit 33A, the second light emitting unit 33B, and the third light emitting unit 33C may each have any laminated structure as long as it includes light emitting layers made of at least an organic compound. For example, each of the first light emitting unit 33A, the second light emitting unit 33B, and the third light emitting unit 33C may be configured such that an electron injection layer, a hole blocking layer, and the like are arranged on the first electrode 31 side of the light emitting layer and a hole injection layer, an electron blocking layer, and the like are arranged on the second electrode 32 side of the light emitting layer.

The first electron transport layer 35A, the second electron transport layer 35B, and the third electron transport layer 35C each have the same configuration as that of the electron transport layer 14 in the aforementioned first embodiment.

The first hole transport layer 37A, the hole transport layer 37B, and the third hole transport layer 37C each have the same configuration as that of the hole transport layer 16 in the aforementioned first embodiment.

The first light emitting layer 36A included in the first red light emitting unit 33A, the second light emitting layer 36B included in the second red light emitting unit 33B, and the third red light emitting layer 36C included in the third red light emitting unit 33C have the same configuration as that of the light emitting layer 15 in the aforementioned first embodiment.

The first charge generating layer 34A and the second charge generating layer 34B have the same configuration as that of the charge generating layer 24 in the aforementioned second embodiment.

As described above, in the organic EL element 30 of the embodiment, since the difference between the peak wavelength of the red light and the dominant wavelength of the red light is 10 nm or less, the organic EL element 30 can provide the red light with high luminous efficiency. Moreover, the organic EL element 30 of the embodiment has the MPE structure in which the first light emitting unit 33A, the second light emitting unit 33B, and the third light emitting unit 33C are stacked one on top of another with each of the first charge generating layer 34A and the second charge generating layer 34B sandwiched between the corresponding pair of adjacent light emitting units. Accordingly, the organic EL element 30 can provide orange light while achieving high-luminance light emission and long-life driving.

The organic EL element 30 of the embodiment can be thereby preferably used in a special lighting device such as an automobile lighting device.

### Fourth Embodiment

### Lighting Device

An embodiment of the lighting device in the present invention is described.

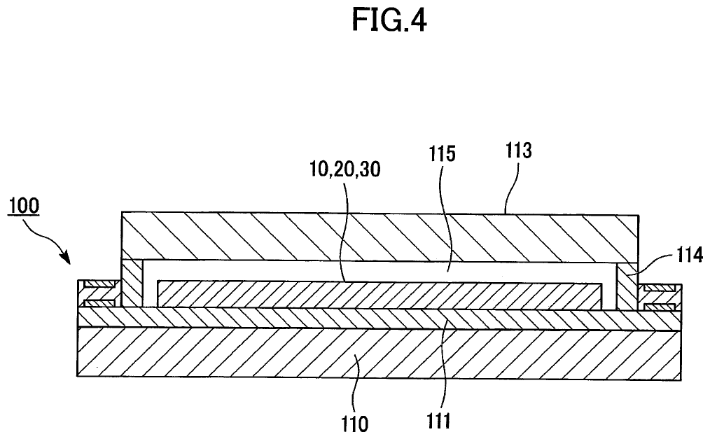

FIG. 4 is a cross-sectional view illustrating a configuration of the lighting device in the present invention. Although an example of the lighting device to which the present invention is applied is described herein, the lighting device of the present invention is not necessarily limited to such a configuration and various changes can be made as appropriate.

The lighting device 100 of the embodiment includes, for example, anyone of the organic EL elements 10, 20, 30 as a light source.

As illustrated in FIG. 4, in the lighting device 100 of the embodiment, multiple anode terminal electrodes 111 and cathode terminal electrodes (illustration omitted) are formed at sides or vertices of a periphery of a glass substrate 110 so that the organic EL element 10, 20, 30 can uniformly emit light. Note that the entire surfaces of the anode terminal electrodes 111 and the entire surfaces of the cathode terminal electrodes are covered with solder (underlying solder) to reduce wiring resistance. Moreover, the anode terminal electrodes 111 and the cathode terminal electrodes uniformly supply an electric current to the organic EL element 10, 20, 30 from the sides or vertices of the periphery of the glass substrate 110. For example, in order to uniformly supply an electric current to the organic EL element 10, 20, 30 formed in a quadrilateral shape, the lighting device 100 includes the anode terminal electrodes 111 on the sides and the cathode terminal electrodes at the vertices. Alternatively, for example, the lighting device 100 includes the anode terminal electrodes 111 on peripheries of L-shaped portions each including a vertex and extending over two sides and the cathode terminal electrodes in center portions of the respective sides.

Moreover, a sealing substrate 113 is arranged on the glass substrate 110 to cover the organic EL element 10, 20, 30 to prevent degrading of the performance of the organic EL element 10, 20, 30 due to oxygen, water, and the like. The sealing substrate 113 is provided on the glass substrate 110 with a peripheral sealing member 114 therebetween. A small gap 115 is provided between the sealing substrate 113 and the organic EL element 10, 20, 30. This gap 115 is filled with a hygroscopic agent. The gap 115 may be filled with, for example, an inert gas such as nitrogen, silicone oil, or the like instead of the hygroscopic agent. Moreover, the gap 115 may be filled with a gel resin in which the hygroscopic agent is dispersed.

Note that, although the glass substrate 110 is used as a base substrate for forming the element in the embodiment, a substrate made of a material such as plastic, metal, or ceramic may also be used. Moreover, in the embodiment, a glass substrate, a plastic substrate, or the like can be used as the sealing substrate 113. When plastic substrates are used as the base substrate and the sealing substrate, the lighting device 100 of the embodiment is flexible.

Moreover, a UV curable resin or a thermal setting resin with low oxygen permeability and low water permeability, a laser glass frit, or the like can be used for the sealing member 114.

The lighting device of the embodiment may have a configuration including an optical film for improving the luminous efficiency, on the light extraction surface side of the organic EL element 10, 20, 30 in the aforementioned embodiment.

The optical film used in the lighting device of the embodiment is provided to improve the luminous efficiency while maintaining the color rendering property.

An organic EL element emits light in a light emitting layer with a higher refractive index (refractive index of about 1.6 to 2.1) than air and it is generally said that only about 15% to 20% of light emitted from the light emitting layer can be extracted. This is because light incident on an interface at an angle equal to or greater than a critical angle is totally reflected and cannot be extracted to the outside of the element. Specifically, light is totally reflected between a transparent substrate and a transparent electrode or the light emitting layer to be guided through the transparent electrode or the light emitting layer and resultantly escapes in directions toward side surfaces of the element.

As a method for improving the extraction efficiency of the light, there are, for example, the following methods: a method of making a surface of the transparent substrate rough to prevent total reflection on an interface between the transparent substrate and air (see, for example, “U.S. Pat. No. 4,774,435”); a method of providing the substrate with a light condensing property to improve the efficiency (see, for example, “Japanese Patent Application Publication No. Sho 63-314795”); a method of forming reflection surfaces on the side surfaces of the element and the like (see, for example, “Japanese Patent Application Publication No. Hei 1-220394”); a method of introducing a flat layer with an intermediate refractive index between the substrate and the light emitting body to form a reflection prevention film (see, for example, “Japanese Patent Application Publication No. Sho 62-172691”); a method of introducing a flat layer with a lower refractive index than the substrate, between the substrate and the light emitting body (see, for example, “Japanese Patent Application Publication No. 2001-202827”); a method of forming a diffraction grading between any two of the substrate, the transparent electrode layer, and the light emitting layer (including between the substrate and the outside) (see, for example, “Japanese Patent Application Publication No. Hei 11-283751”); and the like.

Note that, in order to improve the aforementioned color rendering property, the lighting device 100 may have a structure in which a microlens array or the like is further provided on a surface of the aforementioned optical film or maybe combined with a light condensing sheet. This allows the light to be condensed in a specific direction, for example, a direction frontward of the element light emitting surface, thereby improving the luminance in the specific direction. Furthermore, a light diffusion film may be used together with the light condensing sheet to control a light emission angle from the organic EL element. For example, a light diffusion film (LIGHT-UP) manufactured by Kimoto Co., Ltd. or the like can be used as the light diffusion film.

Note that the present invention is not necessarily limited to the aforementioned embodiment and various changes can be made within a scope not departing from the spirit of the present invention.

Specifically, in the present invention, the aforementioned organic EL elements 10, 20, 30 capable of providing the red light can be preferably used as, for example, a light source of the special lighting device 100 such as the automobile lighting device.

### EXAMPLES

Effects of the present invention are made clearer below by using Experimental Examples.

Note that the present invention is not limited to following Experimental Examples and changes can be made as appropriate within a scope not departing from the spirit of the invention.

### Experimental Example 1

### Manufacturing of Organic EL Element

In Experimental Example 1, an organic EL element having an element structure illustrated in Table 1 was manufactured.

Specifically, first, there was prepared a soda-lime glass substrate with a thickness of 0.7 mm on which an ITO film with a thickness of 100 nm, a width of 2 mm, and a sheet resistance of about 20 Ω/□ was formed.

Then, the substrate was subjected to ultrasonic cleaning by using neutral detergent, ion-exchanged water, acetone, and isopropyl alcohol for 5 minutes for each cleaner and then subjected to spin drying and UV/O₃ treatment.

Next, vapor deposition crucibles (made of tantalum or alumina) in a vacuum deposition apparatus were filled respectively with materials used to form layers illustrated in Table 1. Then, the substrate was set in the vacuum deposition apparatus, electric power was supplied to the vapor deposition crucibles to heat them in a reduced pressure atmosphere with a degree of vacuum of 1×10⁻⁴ Pa or less, and each of the layers was vapor-deposited to a predetermined film thickness at a deposition rate of 0.1 nm per second.

Moreover, the cathode was vapor-deposited to a predetermined film thickness at a deposition rate of 1 nm per second.

### Evaluation of Organic EL Element

The organic EL element of Experimental Example 1 manufactured as described above was connected to a measurement unit driver (trade name: KEITHLEY 2425, manufactured by Keithley Instruments, LLC) and power with a constant current of 3 mA/cm² was supplied to the organic EL element to cause it to emit light in an integrating sphere. Then, the emission spectrum and the luminous flux value of the organic EL element were measured by using a multichannel spectrometer (trade name: USB2000, manufactured by Ocean Optics, Inc.). Moreover, the external quantum efficiency (%) of each of the organic EL elements of Experimental Examples 1 to 6 was calculated based on the result of this measurement. Results are depicted in Table 1.

Furthermore, the difference (nm) between the peak wavelength (A) of the red light and the dominant wavelength (B) of the red light was calculated based on the result of this measurement. Results are depicted in Table 2.

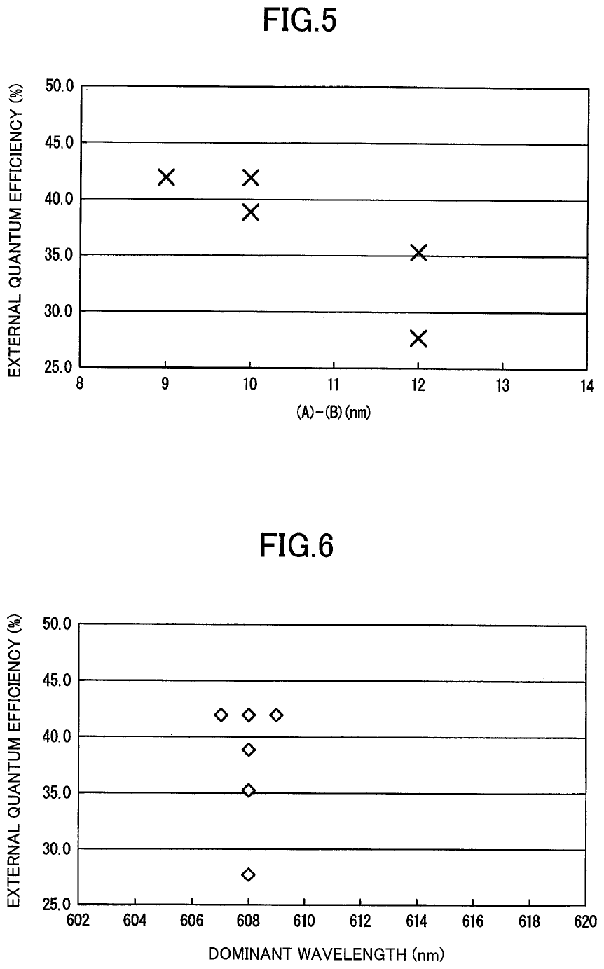

FIG. 5 depicts relationships between the external quantum efficiency (%) and the difference (nm) between the peak wavelength (A) of the red light and the dominant wavelength (B) of the red light. Moreover, FIG. 6 depicts relationships between the external quantum efficiency (%) and the dominant wavelength (B) .

Moreover, Table 3 depicts film thickness (1) from the first light emitting layer to the cathode, film thickness (2) from the second light emitting layer to the cathode, film thickness (3) from the first light emitting layer to the anode, film thickness (4) from the second light emitting layer to the anode, reference film thicknesses of the film thicknesses (1) to (4), and interference conditions. Table 4 depicts a difference between film thickness (1) from the first light emitting layer to the cathode and the reference film thickness, a difference between film thickness (2) from the second light emitting layer to the cathode and the reference film thickness, a difference between film thickness (3) from the first light emitting layer to the anode and the reference film thickness, and a difference between film thickness (4) from the second light emitting layer to the anode and the reference film thickness. The film thickness of each layer was calculated based on an amount of change in the frequency of a crystal oscillator installed in the vacuum deposition apparatus. Note that, in Table 3, since the film thickness of the first light emitting layer and the second light emitting layer is 30 nm and it is conceivable that a light emission site is in a center portion of each light emitting layer, a thickness of 15 nm which is half the film thickness of one light emitting layer is added to each of film thicknesses (1) to (4).

### Experimental Example 2

An organic EL element of Experimental Example 2 having an element structure depicted in Table 1 was manufactured by using the same manufacturing method as in Experimental Example 1.

Then, the organic EL element of Experimental Example 2 was evaluated in the same methods as in Experimental Example 1. The results of the evaluations are depicted in Tables 2 to 4 and FIGS. 5 and 6.

### Experimental Example 3

An organic EL element of Experimental Example 3 having an element structure depicted in Table 1 was manufactured by using the same manufacturing method as in Experimental Example 1.

Then, the organic EL element of Experimental Example 3 was evaluated in the same methods as in Experimental Example 1. The results of the evaluations are depicted in Tables 2 to 4 and FIGS. 5 and 6.

### Experimental Example 4

An organic EL element of Experimental Example 4 having an element structure depicted in Table 1 was manufactured by using the same manufacturing method as in Experimental Example 1.

Then, the organic EL element of Experimental Example 4 was evaluated in the same methods as in Experimental Example 1. The results of the evaluations are depicted in Tables 2 to 4 and FIGS. 5 and 6.

### Experimental Example 5

An organic EL element of Experimental Example 5 having an element structure depicted in Table 1 was manufactured by using the same manufacturing method as in Experimental Example 1.

Then, the organic EL element of Experimental Example 5 was evaluated in the same methods as in Experimental Example 1. The results of the evaluations are depicted in Tables 2 to 4 and FIGS. 5 and 6.

### Experimental Example 6

An organic EL element of Experimental Example 6 having an element structure depicted in Table 1 was manufactured by using the same manufacturing method as in Experimental Example 1.

Then, the organic EL element of Experimental Example 6 was evaluated in the same methods as in Experimental Example 1. The results of the evaluations are depicted in Tables 2 to 4 and FIGS. 5 and 6.

TABLE 1

| | Experi- | Experi- | Experi- | Experi- | Experi- | Experi- |
|---|---|---|---|---|---|---|
| | mental | mental | mental | mental | mental | mental |
| | Example | Example | Example | Example | Example | Example |
| | 1 | 2 | 3 | 4 | 5 | 6 |
| First electrode | 100 nm | 100 nm | 100 nm | 100 nm | 100 nm | 100 nm |
| First electron | 75 nm | 75 nm | 75 nm | 75 nm | 85 nm | 75 nm |
| transport layer | | | | | | |
| First red light | 30 nm | 30 nm | 30 nm | 30 nm | 30 nm | 30 nm |
| emitting layer | | | | | | |
| First hole | 60 nm | 65 nm | 65 nm | 65 nm | 85 nm | 85 nm |
| transport layer | | | | | | |
| Charge generating | 11 nm | 6 nm | 6 nm | 6 nm | 6 nm | 6 nm |
| layer | | | | | | |
| Second electron | 74 nm | 74 nm | 74 nm | 54 nm | 54 nm | 64 nm |
| transport layer | | | | | | |
| Second red light | 30 nm | 30 nm | 30 nm | 30 nm | 30 nm | 30 nm |
| emitting layer | | | | | | |
| Second hole | 130 nm | 130 nm | 130 nm | 130 nm | 130 nm | 130 nm |
| transport layer | | | | | | |
| Second electrode | 100 nm | 100 nm | 150 nm | 150 nm | 150 nm | 150 nm |

TABLE 2

| | Peak | Dominant | | External |
|---|---|---|---|---|
| | wavelength | wavelength | | quantum |
| | (A) | (B) | (A) − (B) | efficiency |
| | [nm] | [nm] | [nm] | [%] |
| Experimental | 620 | 608 | 12 | 35.3 |
| Example 1 | | | | |
| Experimental | 620 | 608 | 12 | 27.8 |
| Example 2 | | | | |
| Experimental | 619 | 609 | 10 | 41.8 |
| Example 3 | | | | |
| Experimental | 617 | 608 | 9 | 42.0 |
| Example 4 | | | | |
| Experimental | 618 | 608 | 10 | 38.9 |
| Example 5 | | | | |
| Experimental | 617 | 607 | 10 | 41.9 |
| Example 6 | | | | |

TABLE 3

| | Film thickness | Film thickness | Film thickness | Film thickness |
|---|---|---|---|---|
| | from first red | from second red | from first red | from second red |
| | light emitting | light emitting | light emitting | light emitting |
| | layer to cathode | layer to cathode | layer to anode | layer to anode |
| | [nm] | [nm] | [nm] | [nm] |
| Experimental Example | 90 | 265 | 420 | 245 |
| 1 | | | | |
| Experimental Example | 90 | 265 | 420 | 245 |
| 2 | | | | |
| Experimental Example | 90 | 265 | 470 | 295 |
| 3 | | | | |
| Experimental Example | 90 | 245 | 470 | 295 |
| 4 | | | | |
| Experimental Example | 100 | 275 | 470 | 295 |
| 5 | | | | |
| Experimental Example | 90 | 275 | 480 | 294 |
| 6 | | | | |
| Reference film | 86 | 258 | 517 | 344 |
| thickness | | | | |
| Interference | (2N − 1)λ/4n | (2N − 1)λ/4n | 2Nλ/4n | 2Nλ/4n |
| condition | N = 1 | N = 2 | N = 3 | N = 2 |

TABLE 4

| | Difference between | Difference between | Difference between | Difference between |
|---|---|---|---|---|
| | film thickness | film thickness | film thickness | film thickness |
| | from first red | from second red | from first red | from second red |
| | light emitting | light emitting | light emitting | light emitting |
| | layer to cathode | layer to cathode | layer to anode and | layer to anode and |
| | and reference film | and reference film | reference film | reference film |
| | thickness | thickness | thickness | thickness |
| | [nm] | [nm] | [nm] | [nm] |
| Experimental | 4 | 7 | −97 | −99 |
| Example 1 | | | | |
| Experimental | 4 | 7 | −97 | −99 |
| Example 2 | | | | |
| Experimental | 4 | 7 | −47 | −49 |
| Example 3 | | | | |
| Experimental | 4 | −13 | −47 | −49 |
| Example 4 | | | | |
| Experimental | 14 | 17 | −47 | −49 |
| Example 5 | | | | |
| Experimental | 4 | 17 | −37 | −49 |
| Example 6 | | | | |

As depicted in Table 2 and FIG. 5, in the organic EL elements of Experimental Examples 3 to 6, the difference between the peak wavelength (A) of the red light and the dominant wavelength (B) of the red light was 10 nm or less and the external quantum efficiency was 38.9% or more. Meanwhile, in the organic EL elements of Experimental Examples 1 and 2, the difference between the peak wavelength (A) of the red light and the dominant wavelength (B) of the red light was 12 nm and the external quantum efficiency was 35.3% or less. Accordingly, it was found that a lighting device including such an organic EL element can provide red light with high luminous efficiency while achieving high-luminance light emission.

Moreover, as depicted in FIG. 6, no relationship was found between the dominant wavelength of the red light and the external quantum efficiency. Accordingly, it was found that it is impossible to estimate the external quantum efficiency and improve the luminous efficiency of the organic EL element only by measuring the dominant wavelength of the red light.

When the luminance efficiency of an organic EL element in the forward direction is to be improved, the organic EL element is generally configured such that the distance dl from the first light emitting layer to the first electrode and the distance d3 from the second light emitting layer to the first electrode satisfy (2N+1)λ/4n (N is a positive integer, λ is a peak wavelength in light emission of the organic EL element, and n is an average refractive index of layers forming the organic EL element). Moreover, the organic EL element is configured such that the distance d2 including the film thickness from the first light emitting layer to the second electrode and the distance d4 including the film thickness from the second light emitting layer to the second electrode satisfy 2Nλ/4n (N is a positive integer, λ is a peak wavelength in light emission of the organic EL element, and n is an average refractive index of layers forming the organic EL element). It is known that this can improve the luminous efficiency by means of an interference effect between light emission of the first light emitting layer and light emission of the second light emitting layer.

For example, in the organic EL element of Experimental Example 6, when the peak wavelength λ is 617 nm and the average refractive index n of layers is 1.8, the reference film thickness for the film thickness (2) from the second light emitting layer to the cathode is calculated as 257 nm in the interference condition (2N−1)λ/4n, where N=2.

As depicted in Table 3, it was found that, in the organic EL elements of Experimental Examples 1 and 2 with low external quantum efficiencies, the film thickness (3) from the first light emitting layer to the anode and the film thickness (4) from the second light emitting layer to the anode deviate greatly from the reference film thicknesses thereof. In other words, in a design using the interference effect, an organic EL element with high luminous efficiency can be achieved by reducing the deviation of each of the aforementioned film thicknesses (1) to (4) from the reference thickness thereof.

However, in a general organic EL element, the optical film thickness varies depending on the shifting of the light emitting region caused by differences in charge transport capabilities of the respective layers. Accordingly, the element structure cannot be optimized merely by setting the film thickness of each layer equal to the reference film thickness. Thus, organic EL elements in which the difference between the peak wavelength of the red light and the dominant wavelength of the red light is within a predetermined range are manufactured to quantify effects of the aforementioned deviation from the reference film thickness and the variation in the optical film thickness caused by the shifting of the light emitting region. The luminous efficiency of the organic EL element can be thereby improved. As a result, a guideline for design of the organic EL element can be made clearer.

### Industrial Applicability

According to one aspect of the present invention, it is possible to provide an organic electroluminescent element which emits color light other than white light with high luminous efficiency and which is suitable for a special lighting device such as an automobile lighting device and to provide a lighting device including this organic electroluminescent element.

### DESCRIPTION OF REFERENCE NUMERALS

10, 20, 30 organic EL element
11, 21, 31 first electrode
12, 22, 32 second electrode
13 light emitting unit
14 electron transport layer
15 light emitting layer
16 hole transport layer
23A, 33A first light emitting unit
23B, 33B second light emitting unit
24 charge generating layer
25A, 35A first electron transport layer
25B, 35B second electron transport layer
26A, 36A first light emitting layer
26B, 36B second light emitting layer
27A, 37A first hole transport layer
27B, 37B second hole transport layer
33C third light emitting unit
34A first charge generating layer
34B second charge generating layer
35C third electron transport layer
36C third light emitting layer
37C third hole transport layer
100 lighting device
111 anode terminal electrode
113 sealing substrate
114 sealing member
115 gap

1. An organic electroluminescent element having a light emitting unit including a light emitting layer made of at least an organic compound between a first electrode and a second electrode, characterized in that
the organic electroluminescent element comprises at least one light emitting unit including a light emitting layer formed of a red light emitting layer which emits red light with a peak wavelength in a red wavelength band,
the red light produced by light emission of the light emitting unit has the peak wavelength in a red wavelength band of 590 nm to 640 nm, and
a difference between the peak wavelength of the red light and a dominant wavelength of the red light is 10 nm or less.

2. The organic electroluminescent element according to claim 1, characterized in that
the red light emitting layer has one or two peak wavelengths in the red wavelength band, and
the red light produced by the light emission of the light emitting unit has one or two peak wavelengths in the red wavelength band of 590 nm to 640 nm.

3. The organic electroluminescent element according to claim 1, characterized in that the red light emitting layer is formed of a red fluorescent light emitting layer containing a red fluorescent material.

4. The organic electroluminescent element according to claim 3, characterized in that the red light provided by the light emitting unit including the red fluorescent light emitting layer includes a delayed fluorescence component.

5. The organic electroluminescent element according to claim 1, characterized in that the red light emitting layer is formed of a red phosphorescent light emitting layer containing a red phosphorescent material.

6. The organic electroluminescent element according to claim 1, characterized in that
the organic electroluminescent element comprises two of the light emitting units which are identical, and
the light emitting units emit red light with the same peak wavelength.

7. The organic electroluminescent element according to claim 1, characterized in that
the organic electroluminescent element comprises two of the light emitting units which are different from each other, and
the light emitting units emit red light with different peak wavelengths, respectively.

8. The organic electroluminescent element according to claim 7, characterized in that the red light has one peak wavelength in a red wavelength band of 590 nm to 620 nm and one peak wavelength in a red wavelength band of 625 nm to 640 nm.

9. The organic electroluminescent element according to claim 1, the organic electroluminescent element having a structure in which a plurality of light emitting units each including a light emitting layer made of at least an organic compound are stacked one on top of the other between the first electrode and the second electrode with a charge generating layer sandwiched between the light emitting units, the organic electroluminescent element capable of providing the red light by causing the plurality of light emitting units to emit light, characterized in that
the organic electroluminescent element comprises:
a first red light emitting unit formed of the light emitting unit; and
a second red light emitting unit formed of the light emitting unit,
the first red light emitting unit and the second red light emitting unit are stacked one on top of the other with a first charge generating layer sandwiched therebetween, and
the organic electroluminescent element has a structure in which the second electrode, the second red light emitting unit, the first charge generating layer, the first red light emitting unit, and the first electrode are stacked one on top of another in this order.

10. The organic electroluminescent element according to claim 9, characterized in that
the organic electroluminescent element further comprises a third red light emitting unit formed of the light emitting unit,
the second red light emitting unit and the third red light emitting unit are stacked one on top of the other with a second charge generating layer sandwiched therebetween, and
the organic electroluminescent element has a structure in which the third red light emitting unit and the second charge generating layer are stacked one on top of the other in this order between the second electrode and the second red light emitting unit.

11. The organic electroluminescent element according to claim 9, characterized in that
the charge generating layer is formed of an electrically insulating layer made of an electron accepting material and an electron donating material, and
a specific resistance of the electrically insulating layer is 1.0×10² Ω·cm.

12. The organic electroluminescent element according to claim 11, characterized in that the specific resistance of the electrically insulating layer is 1.0×10⁵ Ω·cm or more.

13. The organic electroluminescent element according to claim 9, characterized in that
the charge generating layer is formed of a mixed layer of different materials and one component of the mixed layer forms a charge transfer complex by redox, and
when voltage is applied between the first electrode and the second electrode, charges in the charge transfer complex move to the first electrode side and the second electrode side to cause holes to be injected into one light emitting unit located on the first electrode side of the charge generating layer and cause electrons to be injected into another light emitting unit located on the second electrode side of the charge generating layer.

14. The organic electroluminescent element according to claim 9, characterized in that
the charge generating layer is formed of a laminate of an electron accepting material and an electron donating material, and
when voltage is applied between the first electrode and the second electrode, in an interface between the electron accepting material and the electron donating material, charges generated by reaction involving electron transfer between the electron accepting material and the electron donating material move to the first electrode side and the second electrode side to cause holes to be injected into one light emitting unit located on the first electrode side of the charge generating layer and cause electrons to be injected into another light emitting unit located on the second electrode side of the charge generating layer.

15. The organic electroluminescent element according to claim 9, characterized in that the charge generating layers contain a compound having a structure expressed by formula (1): 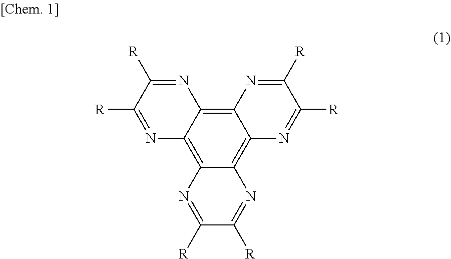
where R represents an electron withdrawing group of F, Cl, Br, I, CN, or CF₃.

16. A lighting device characterized in that the lighting device comprises the organic electroluminescent element according to claim 1.

17. The lighting device according to claim 16, characterized in that the lighting device comprises an optical film on a light extraction surface side of the organic electroluminescent element.

18. The lighting device according to claim 16, characterized in that
the lighting device comprises a base substrate and a sealing substrate which are formed of flexible substrates, and
the lighting device is flexible.
